(19) United States
(12) Patent Application Publication
(10) Pub. No.: US 2017/0127580 A1
(43) Pub. Date: May 4, 2017

(54) SET TOP BOX HAVING PASTE-IN-HOLE TUNER SHIELD

(71) Applicant: THOMSON LICENSING, Issy les-Moulineaux (FR)

(72) Inventors: William John TESTIN, INDIANAPOLIS, IN (US); Mickey Jay HUNT, CAMBY, IN (US); William Hofmann BOSE, NASHVILLE, IN (US); Theodore Paul CORBIN, INDIANAPOLIS, IN (US); Randy Wayne CRAIG, FISHERS, IN (US)

(21) Appl. No.: 15/317,066

(22) PCT Filed: Jun. 5, 2015
(86) PCT No.: PCT/US2015/034381

§ 371 Date: Dec. 7, 2016

Related U.S. Application Data
(60) Provisional application No. 62/010,251, filed on Jun. 10, 2014.

(51) Int. Cl. H05K 9/00; H01R 24/52; H01R 13/6594; H05K 3/34; H05K 1/02

(52) U.S. Cl. CPC H05K 9/0037; H05K 3/3415; H05K 9/0032; H05K 3/3421; H05K 1/0216; H01R 13/6594; H01R 24/52; H05K 2201/10371; H01R 2103/00

(57) ABSTRACT

An electronic device is provided that includes a vertical chassis wall having an aperture; a horizontal circuit board that extends toward the vertical chassis wall; an F-connector connected to the horizontal circuit board on a first side and extending out of the vertical chassis wall through the aperture; and an inner shield that shields a radiofrequency circuit components mounted on the first side of the circuit board. The inner shield includes tabs that extend partially into solder plated clearance holes in the horizontal circuit board and are reflow-soldered into the clearance holes. The tabs have distal ends that terminate between a plane of the first side and a plane of a second side of the circuit board.

### CROSS-REFERENCE TO RELATED APPLICATIONS

This application claims the benefit of U.S. Provisional Application Ser. No. 62/010,251, filed Jun. 10, 2014, which is incorporated by reference herein in its entirety.

### TECHNICAL FIELD

The present principles relate generally to electronic devices and, more particularly, to electronic devices having a radiofrequency tuner shield on a printed circuit board.

### BACKGROUND

The market preference for electronic devices such as set top boxes and the like (e.g. computers, game consoles, DVD players, CD players, etc.) is to have such devices be small, compact, and versatile. However, such preferences increasingly challenge the designers, because set top boxes and the like are required to perform more functions, which require the need for more internal components such as tuners and smart card assemblies in limited interior housing spaces.

Unfortunately, tuners and other components often require shielding within the interior of the housing to shield against radiofrequency interference and/or electrostatic discharge. The introduction of shielding essentially is an additional component which further complicates the designers of such electronic devices.

Additional considerations for designers is the fact that there is increasing pressure to make electronic devices at low cost and to make these devices in a manner that is rapid and easy to inspect.

To appropriately guard at-risk internal components, the common closed polygon vertical wall metal structures or shields have been employed, which are secured generally to a printed circuit board. These have been employed in the high volume manufacturing environments. Some electronic devices of particular interest have satellite receiver functions and include at least one F-connector requiring radiofrequency (RF) interference suppression. Because F-connectors tend to be larger than other components needing suppression or protection and F-connectors tend to have vertical height positions higher than the other components, RF interference suppression designs in devices with F-connectors has often been dictated by the F-connector. For example, one past design was a shield having a single height for the entire tuner shield that was dictated solely by the F-connector which was located at the back wall of the set top box and was located at a vertical position above the planar top surface of the horizontally oriented printed circuit board. Other past designs incorporated two separate tuner shields in which a first shield was a full height shield that covered the F-connector and a second shield had a lower height that covered other components. Another past design simply used a custom or specialized F-connector that had different spatial constraints, but is less preferred because of its higher cost.

With this background in mind, dual height shields for devices with conventional F-connectors have been recently favored over past designs. These dual height shields have thus been employed to accommodate the need to adequately shield higher and/or larger components and also shield adjacent lower and/or smaller components. These dual height shields provide shielding, reduce material use, and further aid in inspection, because the lower height regions of the shield make it easier to see components and connections. An example dual height shield design which is similar to the dual height shield described and used in the current principles is provided in the International Application PCT/US2014/067272 having an international filing date of Nov. 25, 2014.

A benefit of the dual height shield is that once the shield itself is installed, the structure makes it easier to repair or resolder the shield itself, the structure makes it easier to access and repair components within the perimeter of the shield, and the structure makes it easier to view the shield and components. The increase in solderability with such a design is facilitated by having regions with shallow walls. Additionally, the shallow walls make it easier for one to inspect the shield and components following thermal processing and/or other processing steps. Although dual height shields provide many benefits, dual height shields have also had issues. Some of the issues are associated with the nature of manufacturing variability that permits some degree of deviation from perfectly flat printed circuit board mounting surfaces and some degree of deviation from perfectly flat shielding bottoms and/or contact edges. Such deviates from absolute flatness makes it more difficult to solder a tuner shield to the printed circuit board over the entire length of the internal and external walls of the shield, thereby permitting gaps to form between the walls of the shield and the printed circuit board. These gaps can compromise circuit performances and often require a radiofrequency engineer to determine the critical areas that may need to be resoldered or otherwise may need additional attention. In mass production, such gaps have caused the need to design the shield with connection pins at specified regions along the shield contact edges at these critical points in which the pins engage and extend through corresponding mating plated-thru holes that are added to the printed circuit board. Solder paste will be applied only in these areas rather than the entire length of the wall. Due to the length of the pins being large enough to account for the expected variation between the tuner shield contact edges and the printed circuit board mounting surface, the pins which extend through the printed circuit board are guaranteed to provide solder connections in the critical areas. It should be noted that the lower height areas of the dual height shield can be more difficult to keep straight during shipping which can enhance variability.

Further, because of the difficulty of obtaining a large, perfectly flat tuner shield, especially along the bottom edges, and because of the difficulty of obtaining a large perfectly flat printed circuit board, it is difficult to get a tuner shield to solder to a printed circuit over the entire length of the internal and external walls of the shield. This has occurred even when it was deemed necessary to solder an entire wall edge. In other words, gaps between the printed circuit board surface and the shield edges appear to consistently exist that influence the quality of soldering.

At one point, it was thought that complete soldering around the entire peripheral walls would enhance shielding. However, attempts to completely solder the periphery were ineffective in mass production, because, as suggested above, not all gaps could be appropriately soldered to facilitate reliable shielding and some of these gap locations have been in areas critical to circuit performance causing the manufactured device to not operate properly.

The reality is that dual height shields have typically been applied to circuit boards by reflow-soldering which has required 100% inspection of the solder connections in the walls and often required the operators on the production line to rework or “touch-up” the solder connections. The “touch up” soldering is typically done with conventional soldering irons that tend to be large in comparison to the electronic components within the shields. This then would guarantee that the critical areas were soldered. Because of the large number of small surface-mounted components near the solder connections, such components are vulnerable to damage and, in fact, have been damaged during work.

One technique to improve soldering of shields to boards involved the implementation of solder pellets which provides an additional volume of solder in the critical area. The sizes of the pellets have been around the size of a chip component. The added solder was able to bridge moderate gaps between the shield and the board. Although this process worked well, the solder pellets add costs to the manufacturing process.

In the past, tuner shields had been added to boards after the reflow process and then the shields were later wave soldered. The tabs for the tuner shields would extend through the board and were then soldered when the printed circuit board ravels over a wave of solder. This process worked well assuming the tabs are in critical areas. The challenge, however, was this technique, as well as others that involved clearance holes in the printed circuit board, caused designers to make sure that bottom side components were kept laterally away from the shielded area and also caused the manufacturer to shield the bottom side components from the wave solder process. However, in recent designs, because of consumer demand for smaller devices, the sizes of the circuit boards must decrease resulting in the need for more of the circuit board area to be utilized. This makes it difficult to include some components in the devices such as smartcard connectors in the vicinity of the shield.

Hence, the current principles can include a shield design and process that avoids underside processing of the shield and permits underside components such as smartcard assemblies to overlap laterally with the shield.

In light of the above mentioned background, the current principles can provide an improved cost effective electronic device having a printed circuit board, electronic components requiring shielding, and a shield and to provide a method of manufacturing the improved electronic device that addresses the above mentioned drawbacks and disadvantages.

### SUMMARY OF THE PRESENT PRINCIPLES

An electronic device in one embodiment of the present principles is disclosed that includes a vertical chassis wall having an aperture; a horizontal circuit board that extends toward the vertical chassis wall; an F-connector connected to the horizontal circuit board and extending out of the vertical chassis wall through the aperture; and an inner shield that can generally be used to contain or shield the radiofrequency circuit components mounted on the circuit board. The inner shield can comprise two parts: a proximal part near the F-connector that has a larger height and a distal part away from the F-connector that has a smaller height. The inner shield includes tabs that extend partially into solder plated clearance holes in the horizontal circuit board and are soldered into the clearance holes.

Another aspect of the present principles provides a method of manufacturing an electronic device such as a set top box or the like that includes providing a circuit board that supports electronic components on a first or top surface and providing a tuner or radiofrequency shield that will surround the electronic components, wherein the tuner shield can be the dual height shield. The method can include determining locations on the surface of the circuit board and corresponding locations along a bottom or contact edge of the shield that correspondingly serve as holes in the circuit board and pins or mating extensions of the shield, wherein the locations are positions that are critical regions for shielding the electronic components from radiofrequency interference. Further, the feet can be formed to extend at least partially through the circuit board and wherein the holes can be plated in preparation for soldering in which the soldering can occur in reflow oven. The method can include forming the radiofrequency shield to have a higher height shield region that forms at least one higher height shield room and a lower height shield region that forms a lower height shield room. The method can include forming the radiofrequency shield to have shield rooms and attaching portions of less than 100% of straight interior vertical walls of the shield rooms to the printed circuit board by reflow-soldering.

### BRIEF DESCRIPTION OF THE DRAWINGS

The present principles may be better understood in accordance with the following exemplary figures, in which:

FIG. 1 shows a perspective rear view of an electronic device that employs a radiofrequency shield according to the current principles;

FIG. 2 shows perspective views of the shield cover and dual height radiofrequency shield according to the current principles;

FIG. 3 is a top plan view of the dual height radiofrequency shield according to the current principles;

FIG. 4 shows a top plan view of the dual height radiofrequency shield on a printed circuit board according to the current principles;

FIG. 5 shows a perspective view of the dual height radiofrequency shield according to the current principles;

FIG. 6 shows top views of the dual height radiofrequency shield and printed circuit board according to the current principles;

FIG. 7 shows a cross section view of the contact points on the circuit board and the associate solder pins or feet of the shield;

FIG. 8 is a perspective view of the dual height radiofrequency shield on a printed circuit board according to the current principles; and

FIG. 9 is a flowchart for the method of forming the electronic device according to the current principles.

### DETAILED DESCRIPTION

The invention will now be described in greater detail in which embodiments of the present principles are illustrated in the accompanying drawings.

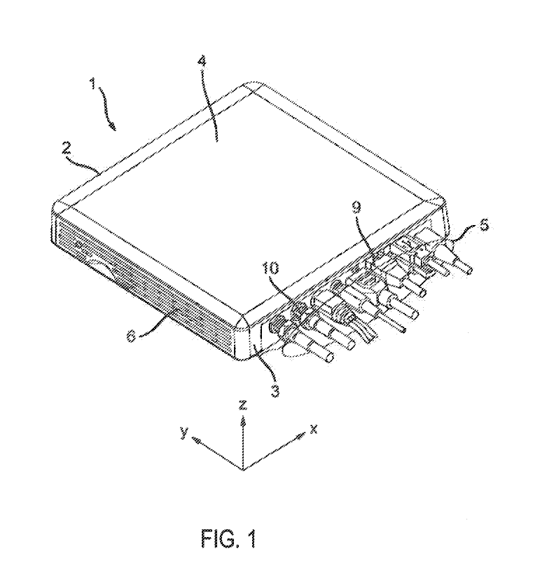

FIG. 1 shows an electronic device 1 such as a set top box or the like having a front wall 2, a rear wall 3, a top 4, and side walls 6 according to the present principles. The electronic device 1 can be a set top box or the like such as computers, game consoles, DVD players, CD players, etc. The device can further include a panel jack 5 for connecting cables 9, wherein one of the electrical connectors can be an F-connector 10 or the like. This view with the plurality of cables 9 connected to the electrical connectors on the panel jack 5 is indicative of how crowded the components within the electronic device 1 can be. Such electronic devices 1 which can have a tuner or the like will require a tuner shield or radiofrequency shield. In this view, one of the electrical connectors on the panel jack 5 can be an F-connector 10. Some other connectors on the panel jack 5 can be associated with and connected to other internal components which may require radiofrequency shielding and/or electric discharge shielding.

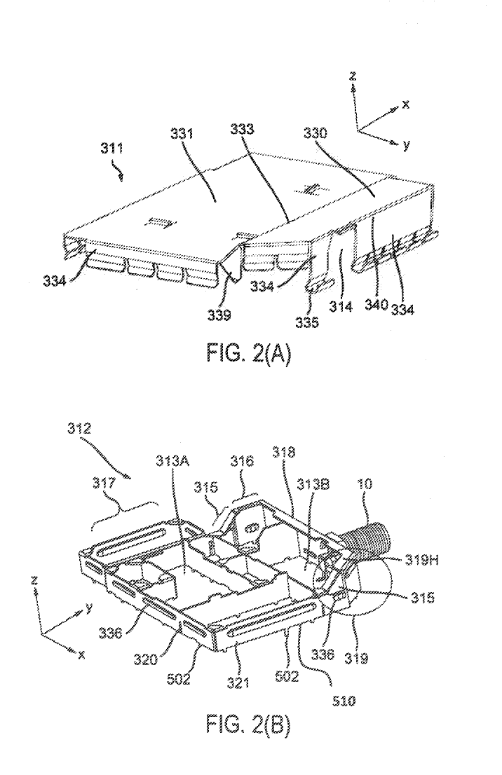

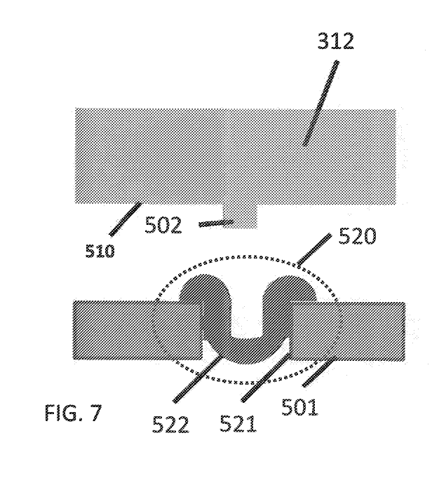

FIGS. 2A and 2B show perspective views of the shield cover 311 and the dual height radiofrequency shield 312 according to the present principles. FIG. 2B most clearly shows the dual height feature of the radiofrequency shield 312 in which the lower height region 317 transitions from the higher height region 316 as the shield extends away from the back wall 318 of the shield along the horizontal y-axis, wherein the comparative heights are gauged along the z-axis. The shield back wall 318 can be parallel to the rear wall 3 of the electronic device 1 along the x-axis. FIG. 2B shows the contact edge 510 of the shield 312 which has plurality of solder pins or feet 502 that will engage corresponding plated through holes 521 at contact points 520 on a printed circuit board 501 shown in FIG. 7 in which the contact points include the hole 521 and solder 522 that plates the hole 521, but the pins or feet 502 only extend partly into the circuit board and not through it.

An advantage of this shield design is that the lower height region 317 makes it easier to repair, optically inspect and troubleshoot the shield 312 and the components contained within the shield 312 after the shield is affixed. Further, this lower height region 317 makes it easier to finish and/or complete the manufacture of the electronic device 1. The lower height region 317 allows for easier soldering and inspecting of the components within the shield and the shield 312 itself, wherein the ease of soldering is enhanced, because the lower height region 317 can have relatively shallow walls. The shallow walls make it easier to see inside the walls of the shield 317 at various stages of manufacturing and after some of these stages, which include thermal processing stages, that can often cause components to move and/or change in some respects. It should be noted that the positioning of the solder pins or feet 502 depends on the requirements of the electronic device and the components therein. Thus, the number and position of the solder pins or feet 502 and corresponding contact points 520 in the printed circuit board 501 can depend and/or be dictated by the wavelengths of the applicable radiofrequency waves.

The shield 312 can be a unitary structure of one folded metal sheet with designed bends and joints, which can be analogous to Origami art in which the solder pins or feet 502 can be formed with the metal sheet. Folded corners 319 can be present and can increase stability. The folded corners 319 include adjacent vertical wall portions and can include a horizontal wall portion 319H extending from the vertical wall portions.

The shield 312 in FIG. 2B has been determined to be effective when an F-connector 10 is employed and connected to the rear wall 3. Because the F-connector is relatively large and the F-connector's positioning is dictated by the required geometry of the electronic device 1 and the required positioning of the horizontal printed circuit within the electronic device 1, the interior part of the F-connector 10 within the electronic device and through the shield back wall 318 tends to be relatively high in the vertical z-axis compared to other components which can be positioned away from the shield back wall 318.

The shield back wall 318 can be parallel to and adjacent to the vertical chassis rear wall 3, the shield front wall 320 can be opposite the shield back wall 318, and at least two outside vertical side wall portions 321 can extend from the shield back wall 318 to the shield front wall 320. The shield walls can be linear or can have bends. The shield back wall, shield front wall, and outside vertical side wall portions comprise the series of vertical peripheral walls. The proximal portion 316 of the vertical peripheral wall is the back wall 318 and the portions of the outside vertical side wall portions connected to the back wall 318 in proximity of the back wall. The proximal portion 316 of the shield near or toward the back wall 318 has a larger height than the distal portion 317 of the vertical peripheral wall near or toward the front wall 320. The outside vertical side wall portions 321 can have an intermediate region 315 in which the proximal portion transitions to the distal portion. In this intermediate region 315, the height of the peripheral wall reduces from a larger height to a lower height.

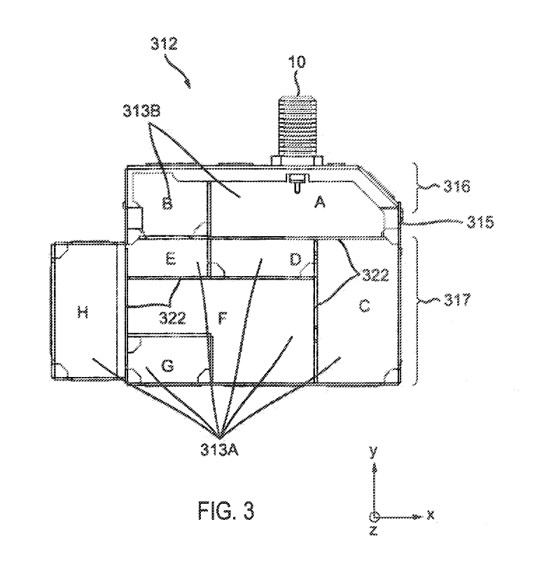

Referring to FIG. 3, the shield 312 can further have interior vertical walls 322 that extend from interior sides of the shield back wall 318, front wall 320, and/or outside vertical sides wall portions 321 and/or other interior vertical walls 322. For example, some of the interior vertical walls such as those used to form shield rooms D and E as shown in FIG. 3 extend to and from other interior vertical walls 322. The collection of interior vertical walls and vertical peripheral walls make a series of separate shielded wall areas, rooms, or compartments, wherein there can be full height shield areas which are proximate the F-connector or first components 10 and associated with the larger height shield regions 316 of the walls and there can be a lower height shield region 317 which is remote from the F-connector or first component 10 and associated with the lower height region of the walls. The larger height dimension of the walls can be positioned such that the larger height is larger than the height or upper vertical position of the F-connector or first component 10. The F-connector or first component 10 can be cylindrical and the larger height dimension of the shield can extend beyond the top vertical positions of the F-connector and other first components 10. The smaller height dimension of the walls can be positioned such that it is smaller or lower than the height of the F-connector or first component and the smaller height dimension can be positioned such that the lowest position is lower than the bottom vertical position of the barrel portion of F-connector and it highest vertical position is located between the lowest and highest positions of the barrel portion of the F-connecter.

The electronic device can further include a top or shield cover 311 for the shield 312 in which the top or shield cover includes at least three portions: a proximate cover portion 330 that covers the proximal portion or the higher height region 316 of the vertical peripheral walls, a distal cover portion 331 that covers the distal portion 317 of the vertical peripheral walls, and intermediate cover portion 333 that covers the intermediate region 315 of the vertical peripheral walls, wherein the proximal portion 316 transitions to the distal portion 317.

The portions 330, 331, 333 can be planar and the perimeter of the shield cover 311 can have generally vertical fingers or flaps or spring clips 334 and extend perpendicularly from the peripheral edge of the shield cover, wherein the fingers or flaps or spring clips 334 extend over the exterior sides of the vertical peripheral walls which can be understood from FIGS. 2A and 2B. The fingers 334 can have edges 335 that bend inward and then outward as they extend from the top cover to create grasping portion which extends over ribs or engage indents 336 in the vertical peripheral walls to secure the top cover to the shield.

As suggested earlier, FIG. 3 also shows that the shield 312 can include a series of shield rooms (A, B, C, D, E, F, G, H) made by the vertical walls. The shield rooms can be classified as the higher height rooms 313B and the lower height rooms 313A. Both types of rooms 313A, 313B can include interior walls 322 and can be made by the interior walls 322. The shield 312 can be attached to the printed circuit board 501 through reflow-soldering.

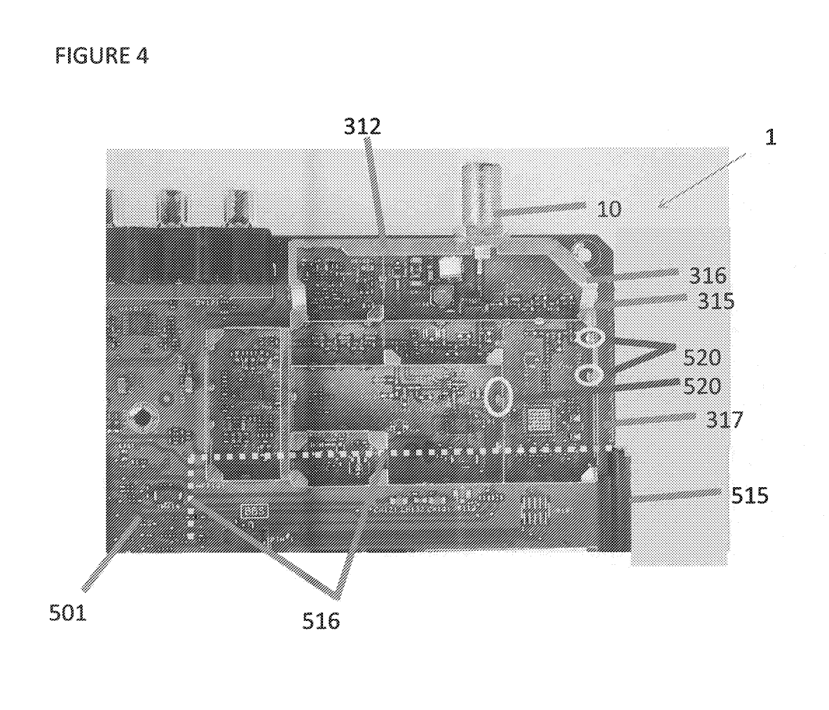

FIG. 4 shows a top plan view of the dual height radiofrequency shield on a printed circuit board 501. FIG. 4 also shows some of the solder points or contact points 520 on the circuit board 501 and further shows how the radiofrequency shield permits other electronic components to be positioned in positions overlapping the shield on the opposite side of the printed circuit board. A smart card outline 516 is exhibited which represents the perimeter of the smart card assembly which can include the smart card bay and smart card. In fact, because of the present principles of the shield and the circuit board, the smart card assembly and other electronic components on the opposite side or underside of the circuit board 501 can laterally overlap the shield and components shielded by the shield 312.

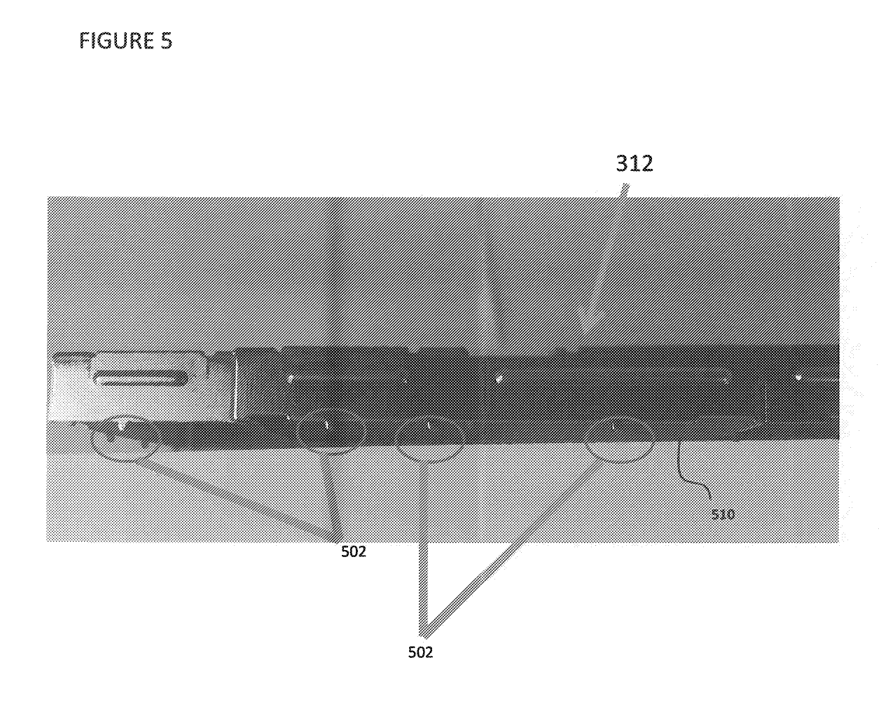

FIG. 5 shows a perspective view of the shield 312 that is to be attached to the printed circuit board 501 at contact points 520, which can be solder points. This view shows how the shield has a contact edge 510 that contacts the circuit board 501 and further has solder tabs, pins or feet 502 extending from the contact edge 510 which are intended to engage at contact points 520.

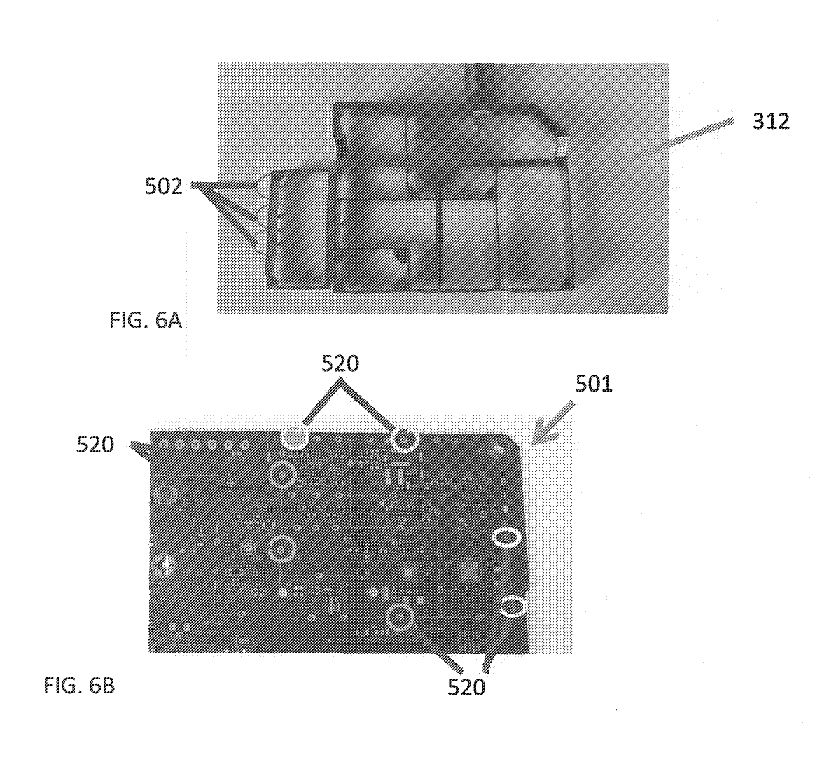

FIG. 6A shows a top view of the dual height radiofrequency shield 312 and FIG. 6B shows a top view of the printed circuit board 501 prior to applying the electronic components to the printed circuit board 501.

FIG. 7 shows a cross section view of the contact points 520 on circuit board 501 at a point in which the circuit board 501 was prepared for further assembly by having holes 521 added to circuit board 501 and having the holes plated with solder 522 for reflow-soldering. The view in FIG. 7 further shows the shield 312 oriented over the circuit board 501 in which the pins 502 on the shield 312 are aligned with the holes 521. At this point, the shield 312 can be applied to the board 501 and the reflow-soldering can commence.

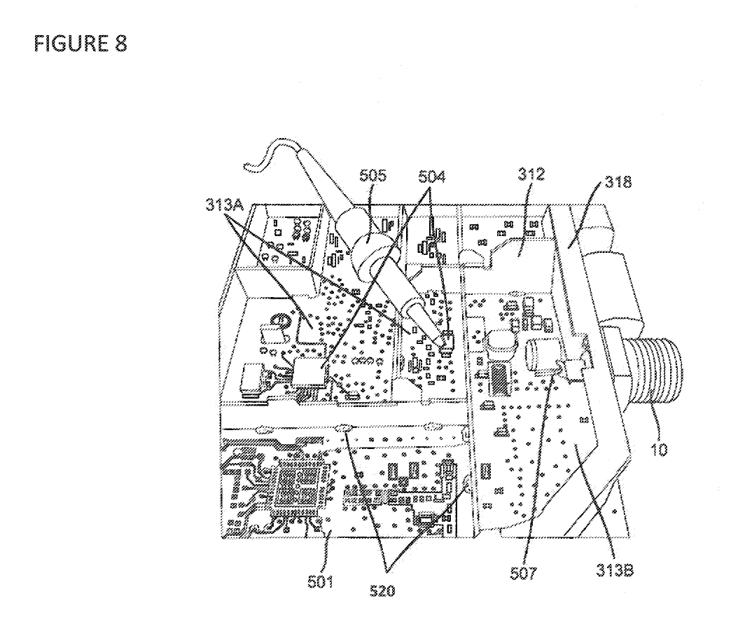

FIG. 8 shows a perspective view of the shield 312 attached to a printed circuit board 501 at contact points 520, which can be solder points. This view shows the soldering or reworking of flat, low or shallow components or second components 504 which can be chip components within the separate shielded wall areas in the lower height rooms 313A by a solder probe, iron or tool 505, wherein these flat, low or shallow components 504 lay lower than the F-connector 10. This view shows how the higher height rooms 313B accommodate the F-connector 10. The F-connector 10 can be considered as a first component at the shield back wall 318.

Experience with the surface-mounted radiofrequency shields has shown that it is difficult to wave-solder along the entire length of the walls of the individual rooms of the shield and testing has demonstrated that only certain critical areas need to be soldered. As such, a feature of the present principles includes providing a minimum number of contact points 520 along the individual vertical walls of each of the rooms of the shield. This reduces time and material usage and minimizes excessive handling which could also increase chances of inadvertent damage to components. As shown in the figures, the number of contact points along a complete linear wall segment of an individual room can be 3 or less. With the use of the disclosed principles, a single shield that has multiple heights can be used, although the present principle can effectively be utilized with a single height shield. In sum, the proposed principles involves locating appropriate pin locations on the shield having single height walls or multiple height walls and appropriate mating hole locations in the printed circuit board at the critical points and connecting the pins to the board with solder paste applied by the standard surface-mounted technology which can be a reflow process in the area of the pins to provide a sufficient connection once the assembly has been processed through the reflow oven. Testing has shown the solder pins or feet 502 are ideally about ˜0.8 mm long when the thickness of the printed circuit board is 1 mm. The holes can penetrate through the board and can have a diameter that is only slightly larger in width than the pins to the extent that they must fit the pins and be large enough to account for tolerances in the pin positions so that 100% of the pins in 100% of the assemblies will properly enter the holes. The holes can be elliptically shaped to have the long dimension be 110-200% of the long lateral dimension of the pin such that pins can be easily accommodated when the pins have a flat vertical geometry commensurate with the wall from which they extend. The holes can have the short lateral dimension being larger than the thickness of the shield wall and can be about 110-200% of the short lateral dimension of the pin. If the pins are round, the holes can be round and have a diameter of about 110-200% of the diameter of the pin. The benefit of elliptical shapes for the holes is they permit some limited lateral adjustments or lateral shifting of the pins that are rectangular in shape along the major and minor axis of the ellipses, but they do not permit substantial rotation or twisting of the pins and the shield.

Some additional features of the current principle can include reflow-soldering the shield at solder points at a limited number of specific areas; reflow-soldering the shield with “over pasting” to increase the amount of solder at only the limited number of locations which can be the critical areas that include the plated holes; reflow-soldering the shield with at least one component that could not be soldered in a wave-solder process, which, for example, can be the tuner F-connector center pin 507 as seen in FIG. 8; reflow-soldering the shield in a designed system that has a component on the side of the circuit board opposite the shield, wherein the “paste-in-hole” process of engaging the pins and hole will not interfere with soldering process, i.e. wave soldering or otherwise, that can be used to attach the components.

The current principles are intended to include situations in which the solder paste is only applied to hole regions and intended to include other situations in which a wall of solder is needed for performance purposes along some shield walls, but the other shields only require the limited number of contact points 520.

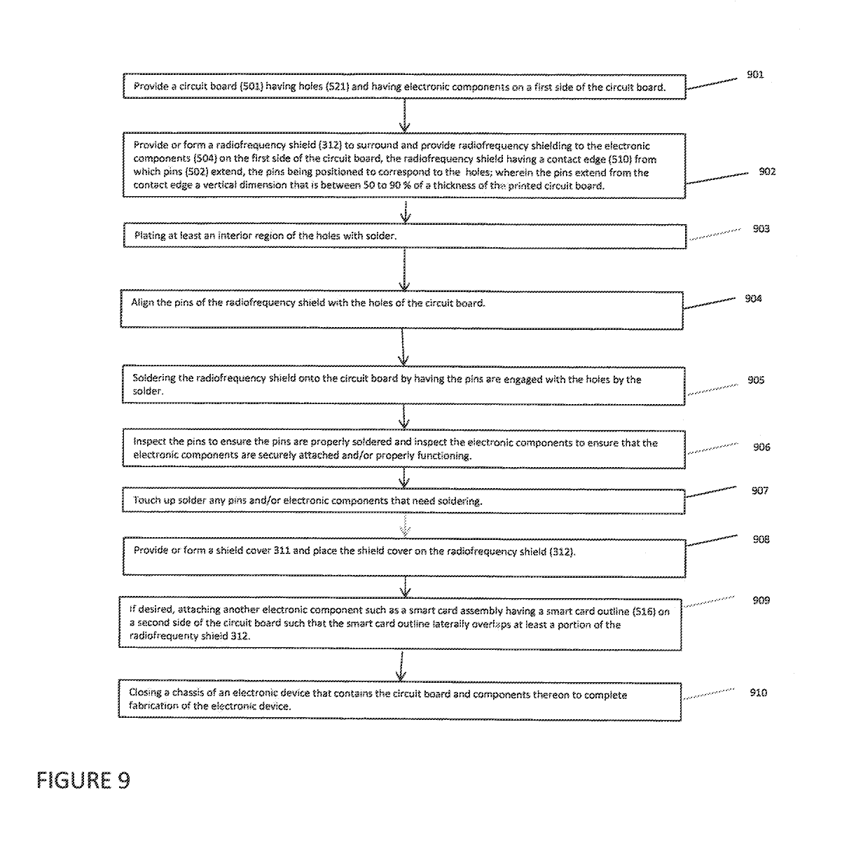

An aspect of the present principle includes the method in which an electronic device is constructed. The method is described in FIG. 9 which can begin with providing in step 901 a circuit board 501 having holes 521 and having electronic components on a first side or top side of the circuit board. Next, in step 902 a radiofrequency shield 312 is formed or provided to surround and provide radiofrequency shielding to the electronic components 504 on the first side of the circuit board. The expressions “to provide” and “providing” in relation to the steps 901 and 902 and in other features that involve components are intended to include making the component, acquiring, or preparing the component for installation. The radiofrequency shield can have pins 502 and a contact edge 510 from which the pins 502 extend. The pins are positioned to correspond to the holes and can extend from the contact edge a vertical dimension that is between 50 to 90% of a thickness of the printed circuit board. In step 903, at least an interior region of the holes is plated with solder. In step 904, the pins of the radiofrequency shield are aligned with the holes of the circuit board. In step 905, the radiofrequency shield is reflow-soldered onto the circuit board in which the pins are engaged with the holes by the solder. In step 906, the pins are inspected to ensure the pins are properly soldered and the electronic components are inspected to ensure that the electronic components are securely attached and/or properly functioning. In step 907, any pins and/or electronic components are touched up by resoldering if more soldering is needed. In step 908, a shield cover 311 is provided or formed and the shield cover is placed on the radiofrequency shield 312. In step 909, if desired or otherwise designed into the device, another electronic component such as a smart card assembly having a smart card outline 516 is attached on a second side or bottom side of the circuit board such that the smart card outline laterally overlaps at least a portion of the radiofrequency shield 312. In step 910, a chassis or the housing of the electronic device that contains the circuit board and components thereon is closed to complete fabrication of the electronic device.

Although the illustrative embodiments have been described herein with reference to the accompanying drawings, it is to be understood that the present principles is not limited to those precise embodiments, and that various changes and modifications may be effected therein by one of ordinary skill in the pertinent art without departing from the scope of the present principles. All such changes and modifications are intended to be included within the scope of the present principles as set forth in the appended claims which can mean that for the process steps disclosed herein the particular and specific order of the steps can be rearranged or reordered where practical and be within the scope of the present principles.

Also, it is intended that the expressions “rear” and “front” and the expressions “vertical” and “horizontal,” as well as other complementary terms are intended to be construed from the perspective of the observer of the figures; and as such, these expression can be interchanged depending upon the direction that the observer looks at the device.

1. A method of producing an electronic device, the method comprising:
acquiring a circuit board having holes and having electronic components on a first side of the circuit board;
acquiring a radiofrequency shield to surround and provide radiofrequency shielding to the electronic components on the first side of the circuit board, the radiofrequency shield having pins and a contact edge from which the pins extend, the pins being positioned to correspond to the holes, said pins being formed to extend from the contact edge and have a distal end which terminates between the first side and a second side of the circuit board;
plating at least an interior region of the holes with solder;
aligning the pins of the radiofrequency shield with the holes of the circuit board; and
soldering the radiofrequency shield such that the radiofrequency shield is soldered onto the circuit board in which the pins are engaged with the holes by the solder.

2. The method of claim 1 comprising:
forming the pins to extend from the contact edge a vertical dimension that is between 50 to 90% of a thickness of the circuit board.

3. (canceled)

4. The method of claim 1 comprising:
forming the holes in the circuit board to be clearance holes.

5. (canceled)

6. (canceled)

7. The method of claim 1 comprising:
determining at least one location on the first side of the circuit board susceptible to radiofrequency interference and corresponding to the contact edge of the radiofrequency shield; and
forming at least one of the holes in said at least one location.

8. (canceled)

9. (canceled)

10. The method of claim 1 comprising:
forming at least one interior vertical wall within the radiofrequency shield to define a first and a second shield rooms; and
forming less than 3 of the holes along any straight interior vertical wall of the first and second shield rooms.

11. The method of claim 1 comprising:
attaching a first electronic component on the first side of the circuit board; and
attaching another electronic component on a second side of the circuit board, wherein the another electronic component laterally overlaps the radiofrequency shield.

12. An electronic device comprising:
an outer housing;
a horizontal circuit board within the outer housing;
at least one first electronic components on a first side of the circuit board;
a plurality of solder plated holes in the circuit board;
a radiofrequency shield attached to the first side of the circuit board, the radiofrequency shield having vertical walls surrounding the first electronic components; and
a plurality of pins corresponding to the solder plated holes and extending from a contact edge of the radiofrequency shield, wherein the radiofrequency shield is attached to the circuit board by having the pins soldered into the soldered plated holes and distal ends of the pins terminate between a plane of the first side and a plane of a second side of the circuit board.

13. The electronic device of claim 12, wherein:
the solder plated holes are clearance holes.

14-17. (canceled)

18. The electronic device of claim 12, wherein said radiofrequency shield has at least one interior vertical wall forming at least one first and one second shield rooms and wherein less than 4 of the pins of the radiofrequency shield are along each vertical wall of the first and second shield rooms of the radiofrequency shield.

19. The electronic device of claim 12, comprising another electronic component on a second side of the circuit board that is opposite the first side, the another electronic component laterally overlapping the radiofrequency shield.

20. The electronic device of claim 12, wherein:
the solder plated holes are elliptical in lateral shape; and
the pins are rectangular in lateral shape.

21. The method of claim 1 comprising:
forming the radiofrequency shield to have shield rooms; and
attaching portions of less than 100% of straight interior vertical walls of the shield rooms by reflow-soldering.

22. The electronic device of claim 12 wherein the pins are formed to extend from the contact edge a vertical dimension that is between 50 to 90% of a thickness of the circuit board.

23. The electronic device of claim 12, wherein said radiofrequency shield has at least one interior vertical wall forming at least one first and one second shield rooms and wherein portions of less than 100% of straight interior vertical walls of the shield rooms are attached to the circuit board.

24. The electronic device of claim 12 comprising an F-connector on the first side of the circuit board.

25. The electronic device of claim 24 wherein the F-connector has an F-connector center pin at one end of the F-connector and a barrel portion, wherein the F-connector center pin is surrounded by the vertical walls of the radiofrequency shield and the barrel portion is connected to the center pin and extends out through an aperture in a back wall 318 of the vertical walls of the radiofrequency shield and out through an aperture in a rear wall of the an outer housing.

26. The electronic device of claim 24, wherein the radiofrequency shield comprises:
a first shield region having a first height that forms at least one first height shield room that surrounds the F-connector center pin; and
a second shield region having a second height that is shorter than the first height that forms at least one second height shield room that surrounds at least one second electronic components on the first side of the circuit board, wherein the first and second shield rooms are formed by the vertical walls of the radiofrequency shield.
